(19) United States
(12) Patent Application Publication
(10) Pub. No.: US 2019/0286515 A1
(43) Pub. Date: Sep. 19, 2019

(54) Dynamic and Preemptive Erasure Encoding in Software Defined Storage (SDS) Systems

(71) Applicant: Martin RAUMANN, San Leandro, CA (US)

(72) Inventor: Martin RAUMANN, San Leandro, CA (US)

(73) Assignee: Softiron Limited, Newark, CA (US)

(21) Appl. No.: 15/921,236

(22) Filed: Mar. 14, 2018

(51) Int. Cl. G06F 11/10; G11C 29/52; H03M 13/15

(52) U.S. Cl. CPC G06F 11/1068; H03M 13/154; G11C 29/52

(57) ABSTRACT

Techniques of erasure encoding that include receiving data for storage, inspecting the data for purposes of erasure encoding, and beginning preemptive erasure encoding of the data without waiting for the data to be completely delivered. The data may be received in packets over a network through an ordered transmission protocol, for example a reliable protocol such as TCP. Inspection of headers of the packets may determine which of the data will be subject to the step of beginning preemptive erasure encoding. This inspection may be “deep packet inspection” as described in more detail below. Also, systems that may perform the foregoing techniques including via use of network interface cards, processors, and/or logic that perform these techniques.

This application is submitted in the name of the following inventor:

| Inventor | Citizenship | Residence City |
|---|---|---|
| Martin RAUMANN | US | San Leandro, CA |

### CROSS-REFERENCE TO RELATED APPLICATION

Not applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND

The present disclosure generally relates to dynamic and preemptive erasure encoding in software defined storage (SDS) systems.

### SUMMARY

Aspects of the subject technology include a technique of erasure encoding includes receiving data for storage, inspecting the data for purposes of erasure encoding, and beginning preemptive erasure encoding of the data without waiting for the data to be completely delivered. The data may be received in packets over a network through an ordered transmission protocol, for example a reliable protocol such as TCP (transmission control protocol).

Inspection of headers of the packets may determine which of the data will be subject to the step of beginning preemptive erasure encoding. This inspection may be “deep packet inspection” as described in more detail below.

The preemptive erasure encoding may be performed based on customer parameters. The customer parameters may include a number or size of data chunks into which the data will be divided and a number of erasure encoding shards that will be created by the preemptive erasure encoding. The customer parameters may be modified for operation at wire speed.

In some aspects, one or more processors of a device that performs the storage may be offloaded from having to perform erasure encoding because of the preemptive erasure encoding. At least part of the preemptive erasure encoding may be performed by one or more network interface cards, which may include one or more field programmable gate arrays that perform at least part of the preemptive erasure encoding.

Some or all of the data and results of the preemptive erasure encoding may be forwarded to local storage and to remote storage.

The subject technology also includes systems that may perform the foregoing techniques. In some aspects, such systems include one or more network interfaces such as a network interface card that receives data for storage, and one or more processors that inspect the data for purposes of erasure encoding and begin preemptive erasure encoding of the data without waiting for the data to be completely delivered. In some aspects, one or more of the systems includes logic adjacent to the one or more network interfaces that performs at least part of the preemptive erasure encoding.

This brief summary has been provided so that the nature of the invention may be understood quickly. Additional steps and/or different steps than those set forth in this summary may be used. A more complete understanding of the invention may be obtained by reference to the following description in connection with the attached drawings.

### BRIEF DESCRIPTION OF THE DRAWINGS

FIG. 1 illustrates prior art erasure encoding.

FIG. 2 illustrates erasure encoding according to aspects of the subject technology.

FIG. 3 illustrates aspects of erasure encoding according to aspects of the subject technology including packet inspection.

FIG. 4 illustrates update of an FPGA to implement aspects of the subject technology.

FIG. 5 illustrates details of one possible implementation of aspects of the subject technology.

FIG. 6 illustrates some additional possible aspects for the subject technology

FIG. 7 is graph showing benefits of an actual implementation of the subject technology.

FIG. 8 is another graph showing benefits of an actual implementation of the subject technology.

### DETAILED DESCRIPTION

Briefly, techniques according to aspects of the subject technology include receiving data for storage, inspecting the data for purposes of erasure encoding, and beginning preemptive erasure encoding of the data without waiting for the data to be completely delivered. The data may be received in packets over a network through an ordered transmission protocol, for example a reliable protocol such as TCP (transmission control protocol).

Inspection of headers of the packets may determine which of the data will be subject to the step of beginning preemptive erasure encoding. This inspection may be “deep packet inspection” as described in more detail below.

The preemptive erasure encoding may be performed based on customer parameters. The customer parameters may include a number or size of data chunks into which the data will be divided and a number of erasure encoding shards that will be created by the preemptive erasure encoding. The customer parameters may be modified for operation at wire speed.

For example, a customer preferably is able to choose any erasure code parameters they wish, even esoteric combinations of k+m. This capability may be achieved by performing erasure encoding according to aspects of the subject technology using a device that includes a network interface card (NIC). The NIC may in turn include at least one field programmable gate array (FPGA). The customer's chosen erasure encoding parameters can be built and dynamically loaded into the FPGA, for example remotely “in the field.”

In some aspects, one or more processors of a device that performs the storage may be offloaded from having to perform erasure encoding because of the preemptive erasure encoding. At least part of the preemptive erasure encoding may be performed by one or more network interface cards, which may include one or more field programmable gate arrays that perform at least part of the preemptive erasure encoding.

Some or all of the data and results of the preemptive erasure encoding may be forwarded to local storage and to remote storage.

The subject technology also includes systems that may perform the foregoing operations. For example, such systems include one or more network interfaces such as a network interface card that receives data for storage, and one or more processors that inspect the data for purposes of erasure encoding and begin preemptive erasure encoding of the data without waiting for the data to be completely delivered. In some aspects, one or more of the systems includes logic adjacent to the one or more network interfaces that performs at least part of the preemptive erasure encoding.

Further non-limiting details about some aspects of the subject technology are set forth in this section. Inclusion of details in this section about general aspects of the subject technology is not an admission that any of the disclosed details are prior art.

Most distributed Software Defined Storage (SDS) product's default replication level provides excellent protection against data loss by storing three copies of your data on different storage nodes. The chance of losing all three disks that contain the same objects, within the period that it takes the SDS system to rebuild from a failed disk, is on the extreme edge of probability. However, storing three copies of data vastly increases both the purchase cost of the hardware and also associated operational costs such as power and cooling. Furthermore, storing copies also means that for every data write, the backend storage must write three times the amount of data. In some scenarios, either of these drawbacks may mean that SDS is not a viable option. Erasure codes are designed to offer a solution. Erasure encoding allows distributed SDS systems to provide more usable storage from the same raw capacity.

Erasure encoding allows SDS systems to achieve either greater usable storage capacity or increase resilience to disk failure for the same number of disks versus the standard replica method. Erasure encoding achieves this by splitting up an object into a number of parts, calculating a type of forward error correction (FEC) code, the erasure code, and storing the results in one or more extra parts. Each part is then stored on a separate drive. These parts are referred to as k shards and M chunks, where k refers to the number of data shards and M refers to the number of erasure code shards. As in RAID, these can often be expressed in the form k+m (k=real data; some number of equal chunks of a data object; M=error correcting data). When the encoding function is called, it returns chunks of the same size to match the size of the data chunks. Data chunks which can be concatenated to reconstruct the original object and encoding chunks which can be used to rebuild a lost chunk.

In more detail, k may represent the number of data chunks, i.e. the number of chunks in which the original object is divided. For instance, if k=2 a 10 KB object will be divided into k objects of 5 KB each. M represents the number of encoding chunks, i.e. the number of additional chunks computed by the encoding functions. Further data can be found at the time of this disclosure at http://docs.ceph.com/docs/master/rados/operations/erasure-code/

One implementation specific detail that is often configured by the customer is the exact values of k+m. As the customer requirements evolve, the values for these parameters may change. In the solution described in this disclosure, a customer specific implementation of k+m, and all the encoding calculations involved in this, can be updated dynamically at any time to generate an accelerated point solution that is customer specific.

In the event of a drive failure which contains an object's shard which is one of the calculated erasure codes, data is read from the remaining drives that store data with no impact. However, in the event of a drive failure which contains the data shards of an object, the SDS can use the erasure codes to mathematically recreate the data from a combination of the remaining data and erasure code shards.

In order to calculate the code bits required for erasure encoding protection, Reed-Solomon and Galois field (finite field) matrix theory with relatively time-consuming software calculations may be employed. When calculated in software, these calculations utilize precious processor resources and also increase traffic latency for data writes and reads that need to be recovered due to missing data. As network speeds increase, these performance drawbacks are exacerbated.

For this reason, erasure encoding pools of storage are often advertised and utilized for large data pools, but with the expected tradeoff of higher main processor utilization and increased latency. These drawbacks have been addressed through various offload attempts into hardware for accelerating these erasure code calculations. However, existing known solutions still require termination of the TCP streams at the processor and an exchange of data with another offload element in order to calculate the erasure code shards. The SoftIron method intends to bypass the need for TCP stream termination before erasure encoding calculation can commence.

Known solutions today claiming to improve the speed of erasure encoding calculations (see Mellanox ConnectX-4) require the processor to initiate and terminate all erasure encoding offload transactions. Prior art on a similar subject as it relates to RAID offload (see U.S. Pat. No. 9,459,957) highlights a network path in the description of possible accelerated paths. However, there are no details on how this is accomplished.

Aspects of the subject technology focus at least in part on accelerating erasure encoding. Some aspects include deep packet inspection of TCP traffic where termination of the traffic is not required before computation can commence. These and other aspects of the subject technology disclosed herein may result in a measurable decrease in latency by performing erasure code calculations of storage data preemptively and in parallel to network stack termination code in the processor. Some of these aspects include deep packet inspection of storage TCP flows in or by one or more network interface card(s) (NICs), one or more of which may include one or more custom field programmable gate array(s) (FPGAs), before the data is expected to be computed by the processor for the same storage flows.

Of note, NICs that implement aspects of the subject technology do not necessarily require a round trip to transfer data into an offload FPGA or other processor to calculate erasure shards. Aspects of the subject technology may achieve this result through deep packet inspection of storage TCP and/or other information flows in by one or more custom FPGA based NICs before data is expected to be computed for storage.

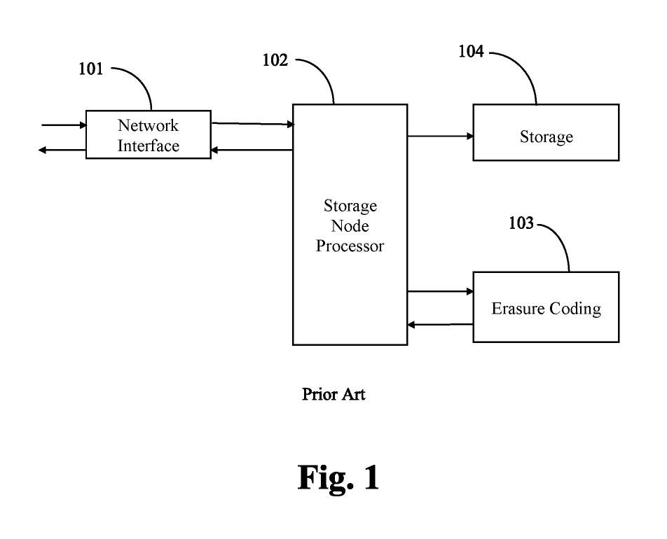

Turning to the figures, FIG. 1 illustrates a prior art implementation of erasure code offload. In the implementation, the following takes place for writing data to storage media.

Data traffic enters the primary storage node via a NIC 101. Data is forwarded to storage node processor 102 for processing. Data is forwarded to the erasure encoding 103 for calculation of erasure code shards. Erasure code shards are returned to the processor. The processor 102 then forwards the original data and/or erasure code shards to at least one end target, namely local storage and/or remote storage 104.

Aspects of the subject technology radically change the foregoing process. With respect to FIG. 1, forwarding of data from network interface 101 to storage node processor 102 and transmission of shards from erasure encoding 103 to storage node processor 102 are combined. Doing so allows both transmission of incoming network packets to the storage node processor and calculation of erasure code shards to occur in parallel. Furthermore, erasure encoding may occur before forwarding to the storage node processor, so no return of the erasure code shards to the storage node processor may need occur.

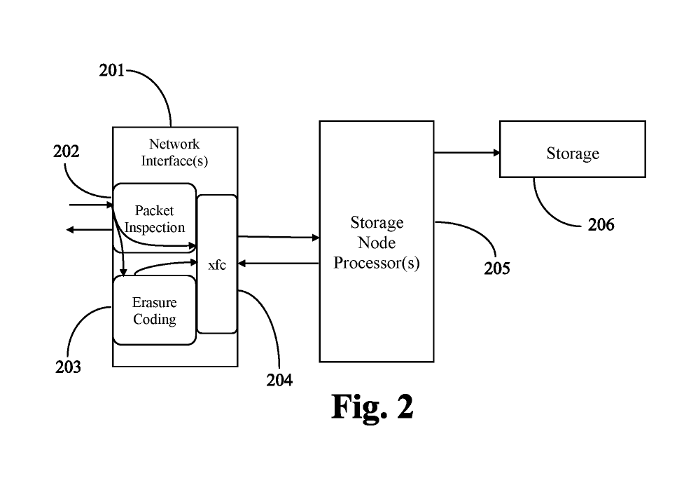

FIG. 2 illustrates erasure encoding according to aspects of the subject technology that may perform the foregoing and other advancements. In general, the figure illustrates a non-limiting example of techniques and/or devices involving an Erasure Code Aware NIC according to aspects of the subject technology.

In the example, network and erasure encoding offload functionality are merged into an FPGA that includes the ability to perform deep packet inspection on incoming network traffic to bypass storage data and preemptively begin erasure code calculations. The FPGA includes normal NIC functionality, deep packet inspection and erasure encoding calculation capabilities, and the ability to easily configure and monitor targeted storage data flows. For the sake of brevity, aspects involving a single FPGA and NIC are described. However, multiple FPGAs and NICs may be used.

Data traffic enters the primary storage node via the network interface card that also includes the erasure code calculation logic.

Internally in the FPGA, traffic identified as belonging to storage flows requiring erasure encoding are copied to the erasure code block internally for erasure code shard calculation.

Both original data and erasure code shards are forwarded to a processor. The processor then forwards to two end targets: (a) the original data and erasure code shards destined to the local storage media, and (b) the original data and erasure code shards destined for remote storage nodes that must go back out over the network.

On possible aspect of the subject technology is storage aware deep packet inspection logic in incorporated into or facilitated by an FPGA in the NIC. This logic preferably has the ability to perform filtering of incoming TCP and/or other data packet header(s) in order to identify and copy packets requiring erasure encoding through a line rate match filter and arbitration scheme. In addition, some out of order packet arrival can be managed using internal and external buffering (memory) on the FPGA.

Local context memory may be used to define the filter used in the header search. This context memory can be programmed manually via the customer or IT professional if the TCP session data for the erasure coded streams are known or can be programmed automatically with additional software provided that works directly with the SDS product of choice to update the context memory as erasure coded pools are added.

Note the shown aspects are not necessarily a TCP/IP offload solution, but rather preferably illustrate a snooper that attempts to identify packet data eventually requiring erasure encoding and thereby may reduce latency of the system by preemptively making calculations that will imminently be requested by the storage node processor.

In some aspects, the transfer of network data to processor(s) during normal operations is not required before being directed back to the hardware for acceleration. Work preferably begins on the erasure code calculations as soon as the Ethernet, TCP, or other frame(s) containing the targeted packet or information related to the subject data hits the ingress network of the storage node. This highlights the benefit of using deep packet inspection to decode the erasure encoding flagged TCP sessions for pre-emptive erasure encode.

In accord with the above, network interface(s) 201 such as NICs, which may include one or more FPGAs, receives data and preferably performs deep packet inspection and/or erasure encoding on the data. The network interface(s) include pack inspection elements 202 and erasure encoding element(s) 203, for example processor(s), memory, and/or other computing elements, that may perform erasure encoding in parallel to reception of the data. Element 204 represents a transceiver to storage node processor(s) 205. The data and/or erasure code data is then sent to local and/or network storage 206.

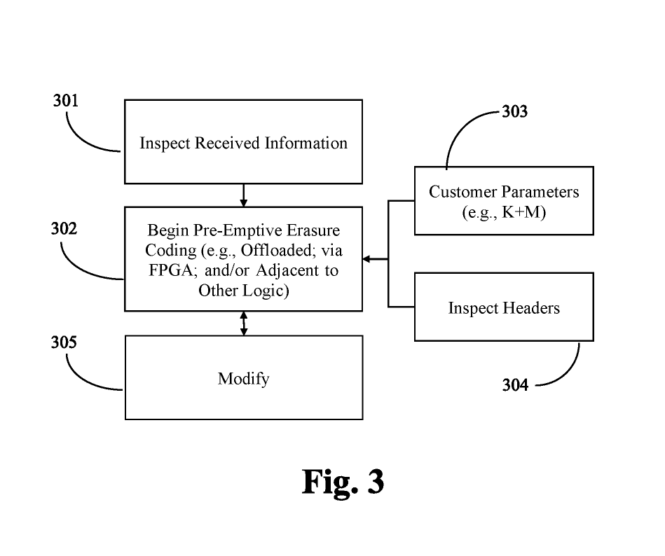

FIG. 3 illustrates additional aspects of erasure encoding including packet inspection according to aspects of the subject technology.

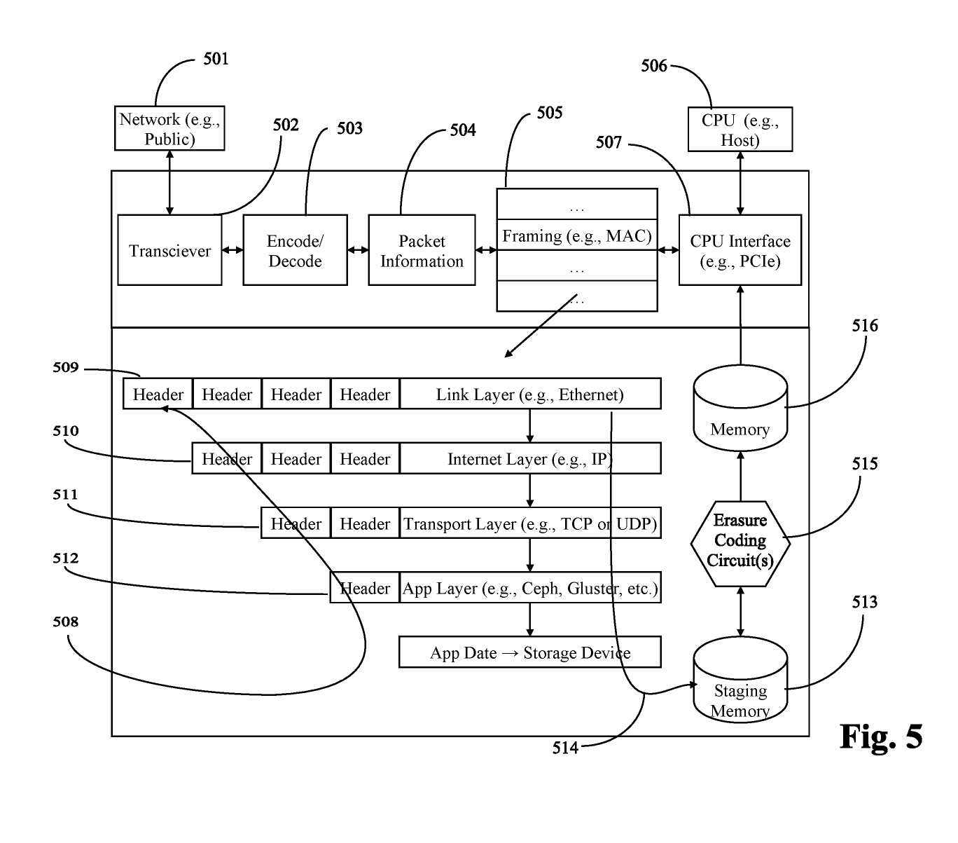

In step 301, received data is inspected. This inspection may involve “deep packet inspection” as described further below, for example with reference to FIG. 5. Pre-emptive erasure encoding occurs or begins in step 302. The pre-emptive encoding may be offloaded from one or more other processors, performed by an FPGA, and/or performed by adjacent to other logic (i.e., processors or code).

Step 303 represents provision and/or acceptance of customer k+m parameters, as discussed above. This data preferably is provided to step 302.

Headers are inspected in step 304. In some aspects, step 304 is part of step 302.

The customer parameters may be modified in step 305, for example to enable operation at wire speed.

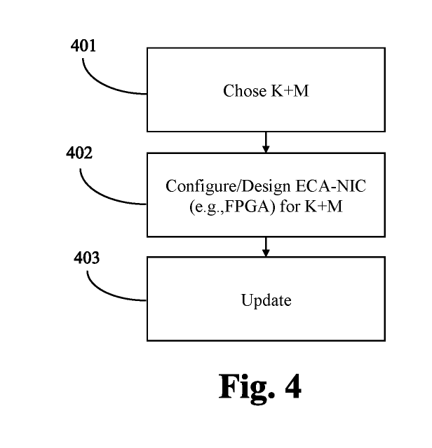

FIG. 4 illustrates update of an FPGA to implement aspects of the subject technology. The FPGA may be one or more FPGAs in one or more NICs that receive data for preemptive erasure encoding according to aspects of the subject technology.

In step 401, k+m values are chosen, specified by a customer, or otherwise determined. In step 402, one or more NICs are configured and/or designed based on the k+m values from step 401. If the NIC(s) include one or more FPGAs, configuration and/or design of the NIC(s) may include configuration and/or design of those FPGA(s).

In step 403, the NIC(s) may be updated, for example to accommodate new k+m values. If the NIC(s) include one or more FPGAs, update may include field and/or other update of the FPGA(s). In preferred aspects, the customer parameters may be modified for operation at wire speed through such updating of the FPGA(s).

Any and/or all of these steps may occur dynamically, for example in real time based on customer inputs and/or requests.

FIG. 5 illustrates details of one possible implementation of aspects of the subject technology. In general, the figure illustrates a non-limiting example of techniques and/or devices involving one or more data paths according to aspects of the subject technology. The example includes deep packet inspection and pre-emptive erasure coding integration.

Network 501 may be a private (e.g., Virtual Private Network—VPN) or public (e.g., the World Wide Web) network from which data for potential pre-emptive erasure encoding may be received. In the case of a VPN, one or more VPN termination (encryption) block(s) may be added.

The data is received by at least one transceiver and/or receiver 502. The data is encoded/decoded by element 503, packet data 504 is determined, and framing such as MAC framing 505 is performed. The resulting data is sent to other steps and/or elements according to aspects of the subject technology as illustrated by the arrow extending from block 505. Data may also be sent from other steps and/or elements. The data preferably also is sent to at least one CPU 506 via at least one CPU interface 507 such as a PCIe, for example to be processed, stored on network storage, and/or further managed for such storage.

Flow 508 represents deep packet inspection of the data from block 505 or any of the other foregoing blocks. For example, the inspection may be of SDS application headers to find data associated with erasure coded pools. Multiple headers, for example based on different transmission protocol layers, may be inspected. Four such headers 509 to 512 are illustrated. Fewer or more headers may be inspected.

Data for pre-emptive erasure encoding preferably is sent to staging memory 513 as represented by flow 514. Use of staging memory may help account for possible out of order data before delivering contiguous blocks for erasure encoding.

Staging memory 513 may be part of one or more FPGAs that reside in or on a NIC and/or are otherwise accessible according to aspects of the subject technology.

This data is then erasure encoded in step/block 515. Again, this step/block preferably is performed by or a part of at least one FPGA that resides in or on a NIC and/or are otherwise accessible according to aspects of the subject technology. Erasure encoding preferably is performed on contiguous data to generate erasure code shard(s) for saving to local memory and/or shipping to network memory in response to requests from the CPUs.

For example, the data and/or code shards may be sent to memory 516 for local storage and/or forwarding to network storage by or under control of CPU 506. In some aspects, staging memory 513 and memory 516 may be the same memory, may contain portions of each other, or may be entirely different.

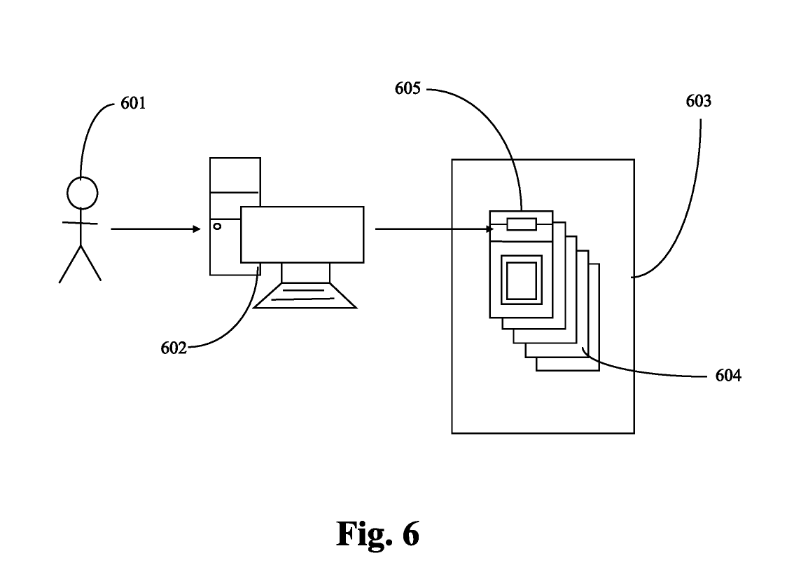

FIG. 6 illustrates some additional possible aspects for the subject technology. In general, the figure illustrates a non-limiting example of an ability to remotely generate an erasure coding offload design that is customer specific. These aspects utilize k+m coding parameters that may be specific to the customer requirements and needs. The coding parameter selections may be entered by the customer into a secure web portal or through some other channel. The hardware design specific to these parameters may then be generated dynamically and pushed to the customer's storage cluster once the design creation is complete. For example, a new FPGA design may be generated and/or updated based on the customer coding specifications. Once one or more FGPAs involved in implementing aspects of the subject technology are updated, the customer may be able to take advantage of acceleration benefits provided by the hardware offload using their unique coding parameters.

Step/block 601 represents a customer choosing k+m erasure encoding parameters depending on their unique application and/or redundancy requirements. Step/block 602 represents designing NIC(s) and/or related FPGA(s) based on those parameters. For example, a bitfile for updating FPGA(s) may be generated. The bitfile and/or other design parameters may be pushed to a customer's computing platform 603, for example in their own or a leased data center. Storage nodes 604 may then be updated through interface 605. This update may occur through a local or remote “push” operation. Alternatively, other techniques for updating the storage nodes such as via a USB drive or other local media may be used.

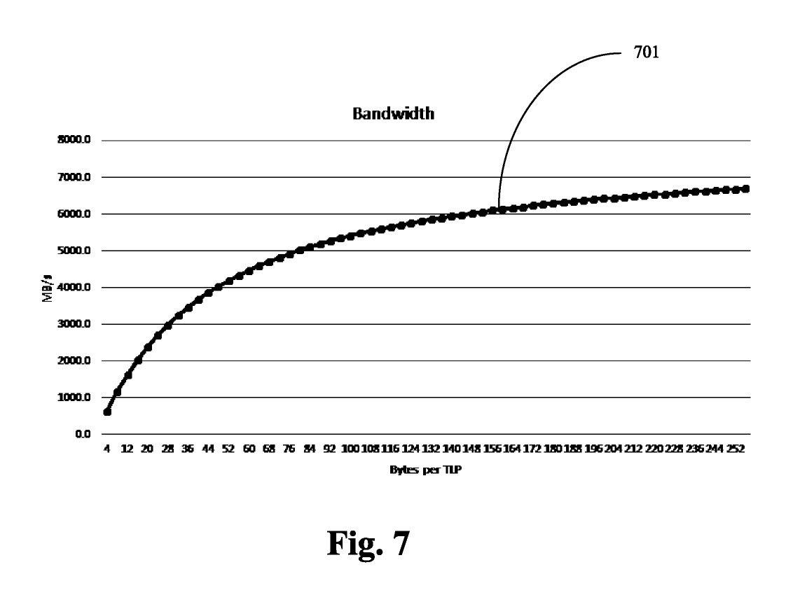

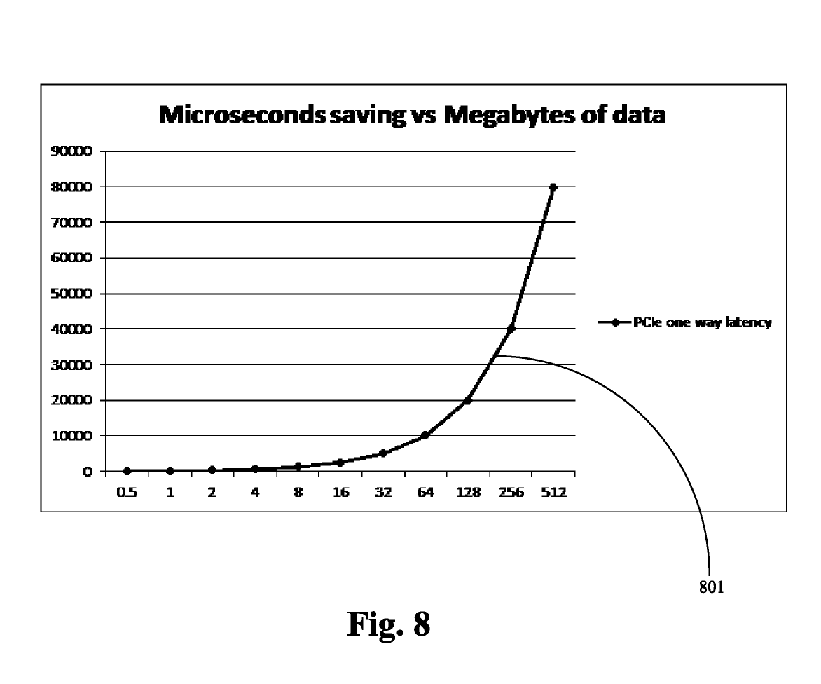

The subject technology has been shown to improve storage efficiency in several experiments. Results of some such experiments are shown in FIGS. 7 and 8. The subject technology is not limited to these results.

These figures show an example of possible latency reduction by a NIC utilizing a PCIe Generation 3, x8 system bus connected to the CPU. Using calculations of bandwidth and latency, we see that the typical one-way latency for a 128-byte PCIe packet is about 19.5 nanoseconds. Note that we stop at 128-byte maximum transfer size because that is the typical size allowed by Intel CPUs to PCIe endpoints.

General specifications for this test were the following:

| | | | includes 128B/130B |
|---|---|---|---|
| PCIe Link | 7.9 | Gb/s | encoding |
| PCIe Lanes | 8 | | |
| Symbol Time | 1.012658 | ns | |
| Data size | 4 | bytes | |
| | | | 64-bit address, 64-bit of |
| TLP Header | 16 | bytes | header |
| DLLP Overhead | 10 | bytes | |
| Total xfer size | 30 | bytes | |
| TLP xfer time | 3.797468 | ns | |
| DLLP xfer time | 1.265823 | ns | |
| TLPs per ACK | 1 | TLPs | |
| TLPs per FC | | | |
| update | 1 | TLPs | |
| Total bytes xfer'd | 4 | bytes | |
| Total xfer time | 6.329114 | ns | |
| Practical BW | 632.0 | MB/s | |

Curve 701 in FIG. 7 illustrates the following results:

| data | total xfer | TLP xfer | | |
|---|---|---|---|---|
| bytes | size | time | Efficiency | Bandwidth |
| 4 | 30 | 3.797468354 | 13.3% | 632.0 |
| 8 | 34 | 4.303797468 | 23.5% | 1170.4 |
| 12 | 38 | 4.810126582 | 31.6% | 1634.5 |
| 16 | 42 | 5.316455696 | 38.1% | 2038.7 |
| 20 | 46 | 5.82278481 | 43.5% | 2393.9 |
| 24 | 50 | 6.329113924 | 48.0% | 2708.6 |
| 28 | 54 | 6.835443038 | 51.9% | 2989.2 |
| 32 | 58 | 7.341772152 | 55.2% | 3241.0 |
| 36 | 62 | 7.848101266 | 58.1% | 3468.3 |
| 40 | 66 | 8.35443038 | 60.6% | 3674.4 |
| 44 | 70 | 8.860759494 | 62.9% | 3862.2 |
| 48 | 74 | 9.367088608 | 64.9% | 4034.0 |
| 52 | 78 | 9.873417722 | 66.7% | 4191.8 |
| 56 | 82 | 10.37974684 | 68.3% | 4337.3 |
| 60 | 86 | 10.88607595 | 69.8% | 4471.7 |
| 64 | 90 | 11.39240506 | 71.1% | 4596.4 |
| 68 | 94 | 11.89873418 | 72.3% | 4712.3 |
| 72 | 98 | 12.40506329 | 73.5% | 4820.3 |
| 76 | 102 | 12.91139241 | 74.5% | 4921.3 |
| 80 | 106 | 13.41772152 | 75.5% | 5015.9 |
| 84 | 110 | 13.92405063 | 76.4% | 5104.6 |
| 88 | 114 | 14.43037975 | 77.2% | 5188.1 |
| 92 | 118 | 14.93670886 | 78.0% | 5266.7 |
| 96 | 122 | 15.44303797 | 78.7% | 5340.8 |
| 100 | 126 | 15.94936709 | 79.4% | 5411.0 |
| 104 | 130 | 16.4556962 | 80.0% | 5477.3 |
| 108 | 134 | 16.96202532 | 80.6% | 5540.3 |
| 112 | 138 | 17.46835443 | 81.2% | 5600.0 |
| 116 | 142 | 17.97468354 | 81.7% | 5656.8 |
| 120 | 146 | 18.48101266 | 82.2% | 5710.8 |
| 124 | 150 | 18.98734177 | 82.7% | 5762.4 |
| 128 | 154 | 19.49367089 | 83.1% | 5811.5 |
| 132 | 158 | 20 | 83.5% | 5858.4 |
| 136 | 162 | 20.50632911 | 84.0% | 5903.3 |
| 140 | 166 | 21.01265823 | 84.3% | 5946.2 |
| 144 | 170 | 21.51898734 | 84.7% | 5987.4 |
| 148 | 174 | 22.02531646 | 85.1% | 6026.8 |
| 152 | 178 | 22.53164557 | 85.4% | 6064.6 |
| 156 | 182 | 23.03797468 | 85.7% | 6101.0 |
| 160 | 186 | 23.5443038 | 86.0% | 6135.9 |
| 164 | 190 | 24.05063291 | 86.3% | 6169.5 |
| 168 | 194 | 24.55696203 | 86.6% | 6201.9 |
| 172 | 198 | 25.06329114 | 86.9% | 6233.0 |
| 176 | 202 | 25.56962025 | 87.1% | 6263.1 |
| 180 | 206 | 26.07594937 | 87.4% | 6292.0 |
| 184 | 210 | 26.58227848 | 87.6% | 6320.0 |
| 188 | 214 | 27.08860759 | 87.9% | 6347.0 |
| 192 | 218 | 27.59493671 | 88.1% | 6373.1 |
| 196 | 222 | 28.10126582 | 88.3% | 6398.3 |
| 200 | 226 | 28.60759494 | 88.5% | 6422.8 |
| 204 | 230 | 29.11392405 | 88.7% | 6446.4 |
| 208 | 234 | 29.62025316 | 88.9% | 6469.3 |
| 212 | 238 | 30.12658228 | 89.1% | 6491.5 |
| 216 | 242 | 30.63291139 | 89.3% | 6513.0 |
| 220 | 246 | 31.13924051 | 89.4% | 6533.8 |
| 224 | 250 | 31.64556962 | 89.6% | 6554.1 |
| 228 | 254 | 32.15189873 | 89.8% | 6573.7 |
| 232 | 258 | 32.65822785 | 89.9% | 6592.8 |
| 236 | 262 | 33.16455696 | 90.1% | 6611.3 |
| 240 | 266 | 33.67088608 | 90.2% | 6629.4 |
| 244 | 270 | 34.17721519 | 90.4% | 6646.9 |
| 248 | 274 | 34.6835443 | 90.5% | 6663.9 |
| 252 | 278 | 35.18987342 | 90.6% | 6680.5 |
| 256 | 282 | 35.69620253 | 90.8% | 6696.7 |

Curve 801 in FIG. 8 illustrates calculated total transfer time for sending larger data objects across the referenced PCIe bus, dividing into the 128 byte maximum transfer size. The graph size ranges from 512 kilobytes up to 512 megabytes in a doubling scale. The latency increases are linear.

The subject technology may be performed by and improve the performance of one or more computing devices. The computing device preferably includes at least a tangible computing element. Examples of a tangible computing element include but are not limited to a microprocessor, application specific integrated circuit, programmable gate array, memristor based device, and the like. A tangible computing element may operate in one or more of a digital, analog, electric, photonic, and/or some other manner. Examples of a computing device include but are not limited to a mobile computing device such as a smart phone or tablet computer, a wearable computing device (e.g., Google® Glass), a laptop computer, a desktop computer, a server, a client that communicates with a server, a smart television, a game console, a part of a cloud computing system, a virtualized computing device that ultimately runs on tangible computing elements, or any other form of computing device. The computing device preferably includes or accesses storage for instructions and data used to perform steps such as those discussed above.

Additionally, some operations may be considered to be performed by multiple computing devices. For example, steps of displaying may be considered to be performed by both a local computing device and a remote computing device that instructs the local computing device to display something. For another example, steps of acquiring or receiving may be considered to be performed by a local computing device, a remote computing device, or both. Communication between computing devices may be through one or more other computing devices and/or networks.

The invention is in no way limited to the specifics of any particular embodiments and examples disclosed herein. For example, the terms “aspect,” “example,” “preferably,” “alternatively,” and the like denote features that may be preferable but not essential to include in some embodiments of the invention. In addition, details illustrated or disclosed with respect to any one aspect of the invention may be used with other aspects of the invention. Additional elements and/or steps may be added to various aspects of the invention and/or some disclosed elements and/or steps may be subtracted from various aspects of the invention without departing from the scope of the invention. Singular elements/steps imply plural elements/steps and vice versa. Some steps may be performed serially, in parallel, in a pipelined manner, or in different orders than disclosed herein. Many other variations are possible which remain within the content, scope, and spirit of the invention, and these variations would become clear to those skilled in the art after perusal of this application.

What is claimed is:

1. A method of erasure encoding, comprising:
receiving data for storage;
inspecting the data for purposes of erasure encoding; and
beginning preemptive erasure encoding of the data without waiting for the data to be completely delivered.

2. The method as in claim 1, wherein the data is received in packets over a network through an ordered transmission protocol.

3. The method as in claim 2, wherein inspection of headers of the packets determines which of the data will be subject to the step of beginning preemptive erasure encoding.

4. The method as in claim 1, wherein the preemptive erasure encoding is performed based on customer parameters.

5. The method as in claim 4, wherein the customer parameters include a number or size of data chunks into which the data will be divided and a number of erasure encoding shards that will be created by the preemptive erasure encoding.

6. The method as in claim 5, wherein the customer parameters are modified for operation at wire speed.

7. The method as in claim 1, wherein one or more processors of a device that performs the storage is offloaded from having to perform erasure encoding because of the preemptive erasure encoding.

8. The method as in claim 7, wherein at least part of the preemptive erasure encoding is performed by one or more network interface cards.

9. The method as in claim 8, wherein the one or more network interface cards include one or more field programmable gate arrays that perform at least part of the preemptive erasure encoding.

10. The method as in claim 1, wherein some or all of the data and results of the preemptive erasure encoding are forwarded to local storage and to remote storage.

11. A system that performs erasure encoding, comprising:
one or more network interfaces that receives data for storage;
one or more processors that inspect the data for purposes of erasure encoding and begin preemptive erasure encoding of the data without waiting for the data to be completely delivered.

12. The system as in claim 11, wherein the data is received in packets over a network through an ordered transmission protocol.

13. The system as in claim 12, wherein inspection of the data comprises inspection of headers of the packets to determine which of the data will be subject to preemptive erasure encoding.

14. The system as in claim 11, wherein the one or more network interfaces comprise one or more network interface cards.

15. The system as in claim 14, wherein the one or more network interface cards comprise one or more field programmable gate arrays that participate in the preemptive erasure encoding.

16. The system as in claim 11, wherein the preemptive erasure encoding is performed based on customer parameters.

17. The system as in claim 16, wherein the customer parameters include a number or size of data chunks into which the data will be divided and a number of erasure encoding shards that will be created by the preemptive erasure encoding.

18. The system as in claim 17, wherein the customer parameters are modified for operation at wire speed.

19. The system as in claim 11, wherein the one or more processors offload one or more other processors from having to perform erasure encoding because of the preemptive erasure encoding.

20. The system as in claim 11, further comprising logic adjacent to the one or more network interfaces that performs at least part of the preemptive erasure encoding.
